(19) United States
(12) Patent Application Publication
(10) Pub. No.: US 2026/0371677 A1
(43) Pub. Date: Nov. 19, 2026

(54) ELECTRODE FORMATION METHOD FOR SEMICONDUCTOR DEVICE

(71) Applicant: JUSUNG ENGINEERING CO., LTD., Gwangju-Si, Gyeonggi-Do (KR)

(72) Inventors: Young Woon KIM, Gwangju-Si, Gyeonggi-Do (KR); Su Vin KIM, Gwangju-Si, Gyeonggi-Do (KR); Seok Jin PARK, Gwangju-Si, Gyeonggi-Do (KR); Yoon Ju LEE, Gwangju-Si, Gyeonggi-Do (KR); Chul Joo HWANG, Gwangju-Si, Gyeonggi-Do (KR); Seung Min YEO, Gwangju-Si, Gyeonggi-Do (KR)

(21) Appl. No.: 19/124,267

(22) PCT Filed: Oct. 24, 2023
(86) PCT No.: PCT/KR2023/016538

§ 371 Date: Apr. 24, 2025

(30) Foreign Application Priority Data
Oct. 25, 2022 (KR) 10-2022-0138373

(51) Int. Cl. H10D 64/01; C23C 30/00; H10P 14/43

(52) U.S. Cl. CPC H10D 64/01; C23C 30/00; H10P 14/43

(57) ABSTRACT

A method for forming an electrode in accordance with an embodiment of the present disclosure may include preparing a substrate, spraying a precursor containing ruthenium (Ru) on the substrate to form a metal thin film layer, first treatment of spraying a first treatment gas containing oxygen (O2) on the substrate, purge of spraying a purge gas after stopping the spraying of the first treatment gas, and second treatment of spraying a second treatment gas containing at least one of hydrogen (H2), argon (Ar), and helium (He) on the substrate to anneal the metal thin film layer.

Therefore, according to embodiments of the present disclosure, it is possible to form an electrode from which ligand impurities resulting from a precursor containing at least one of ruthenium (Ru) and molybdenum (Mo) are removed. Accordingly, it is possible to prepare an electrode with low resistance.

### TECHNICAL FIELD

The present disclosure relates a method for forming an electrode of a semiconductor device, and more particularly, to a method for forming an electrode of a semiconductor device with improved electrical properties.

### BACKGROUND ART

In order to improve electrical properties of a semiconductor device such as a NAND flash, it is necessary to lower the resistance of an electrode.

In forming an electrode of a semiconductor device, the electrode is formed by a method in which a precursor containing a metal is sprayed and deposited on a substrate.

Meanwhile, a precursor used for forming an electrode contains at least one ligand among carbon (C), hydrogen (H), and oxygen (O). However, such ligands act as impurities that increase the resistance of an electrode, and accordingly, there is a problem in which electrical properties of a semiconductor device are degraded.

### Prior Art Document

### Patent Document

(Patent Document 1) Korean Patent Registration No. 10-0942958

### DISCLOSURE OF THE INVENTIVE CONCEPT

### Technical Problem

The present disclosure provides a method for forming an electrode of a semiconductor device, the method capable of lowering the resistance of an electrode.

The present disclosure also provides a method for forming an electrode of a semiconductor device, the method capable of removing impurities.

### Technical Solution

In accordance with an exemplary embodiment, a method for forming an electrode includes a step of preparing a substrate, a step of spraying a precursor containing ruthenium (Ru) on the substrate to form a metal thin film layer, a first treatment step of spraying a first treatment gas containing oxygen (O2) on the substrate, a purge step of spraying a purge gas after stopping the spraying of the first treatment gas, and a second treatment step of spraying a second treatment gas containing at least one of hydrogen (H2), argon (Ar), and helium (He) on the substrate to anneal the metal thin film layer.

The method may further include a first plasma treatment step performed after the first treatment step, and forming oxygen (O2) plasma on the substrate.

The method may further include a first plasma treatment step performed before the first treatment step, and forming oxygen (O2) plasma on the substrate.

The step of forming the metal thin film layer, the first treatment step, the purge step, and the second treatment step may be repeated a plurality of times and performed.

The process temperature of the second treatment step may be adjusted to be higher than that of the first treatment step.

The pressure of the second treatment step may be approximately 5 Torr to approximately 7 Torr.

The substrate in accordance with an exemplary embodiment of the present disclosure may include a trench recessed downward from an upper surface thereof, and the method for forming an electrode in accordance with an exemplary embodiment of the present disclosure may further include a pre-treatment step of exposing the substrate on which the metal thin film layer is formed to oxygen plasma to convert a portion of the metal thin film layer into a gaseous metal oxide, thereby etching the metal thin film layer, wherein the pre-treatment step may be performed between the first treatment step and the purge step, or between the metal thin film formation step and the first treatment step.

When the portion of the metal thin film layer is converted into the gaseous metal oxide in the pre-treatment step, another portion of the metal thin film layer may be converted into a solid metal oxide, the second treatment gas sprayed in the second treatment step may contain hydrogen (H2), and the second treatment step of spraying the second treatment gas containing hydrogen (H2) may be to react the hydrogen (H2) contained in the second treatment gas with the solid metal oxide contained in the metal thin film layer, thereby reducing the solid metal oxide to a metal.

The second treatment step may include a step of generating hydrogen plasma by using the second treatment gas containing hydrogen (H2).

In accordance with another exemplary embodiment, a method for forming an electrode includes a step of preparing a substrate on which an indium gallium zinc oxide (IGZO) thin film layer is formed on one surface thereof, a step of spraying a precursor containing ruthenium (Ru) on the IGZO thin film layer to form a metal thin film layer, a first treatment step of spraying a first treatment gas containing oxygen (O2) on the substrate to remove impurities included in the metal thin film layer, a purge step of spraying a purge gas after stopping the spraying of the first treatment gas, and a second treatment step of spraying a second treatment gas containing argon (Ar) on the substrate to anneal the metal thin film layer.

The method may further include a post-treatment step performed after the second treatment step, and spraying a post-treatment gas containing hydrogen (H2) on the substrate.

In accordance with yet another exemplary embodiment, a method for forming an electrode includes a step of preparing a substrate, a first process cycle step including a step of forming a first metal thin film layer on the substrate, and a second process cycle step including a step of forming a second metal thin film layer on the first metal thin film layer, wherein the first process cycle step includes a step of spraying a precursor containing ruthenium (Ru) on the substrate to form the first metal thin film layer, a first treatment step of spraying a first treatment gas containing oxygen (O2) on the substrate, a purge step of spraying a purge gas after stopping the spraying of the first treatment gas, and a second treatment step of spraying a second treatment gas containing argon (Ar) on the substrate, and the second process cycle step includes a step of spraying a precursor containing ruthenium (Ru) on the first metal thin film layer to form the second metal thin film layer, a third treatment step of spraying a third treatment gas containing oxygen (O2) on the first metal thin film layer, a purge step of spraying a purge gas after stopping the spraying of the third treatment gas, and a fourth treatment step of spraying a fourth treatment gas containing hydrogen (H2) on the first metal thin film layer.

The fourth treatment step may include a step of including a gas containing argon (Ar) before the spraying of the fourth treatment gas.

### Advantageous Effects

According to embodiments of the present disclosure, it is possible to form an electrode from which ligand impurities resulting from a precursor containing at least one of ruthenium (Ru) and molybdenum (Mo) are removed. Accordingly, it is possible to prepare an electrode with low resistance.

In addition, in forming an electrode on a substrate having a trench, step coverage may be improved by reducing the difference between the thickness of a thin film formed on an inner wall forming the trench and the thickness of a thin film formed on an upper surface of the substrate.

### BRIEF DESCRIPTION OF THE DRAWINGS

FIG. 1 is a diagram illustrating a state in which an electrode in accordance with an exemplary embodiment is formed on a substrate;

FIG. 2 is a conceptual diagram for describing the method for forming an electrode in accordance with an exemplary embodiment;

FIG. 3 is a process diagram conceptually illustrating the method for forming an electrode in accordance with an exemplary embodiment;

FIG. 4 is a conceptual diagram showing a method of forming a metal thin film layer on a substrate in accordance with another exemplary embodiment;

FIG. 5 is a process diagram conceptually illustrating a method for forming an electrode in accordance with yet another exemplary embodiment;

FIG. 6 is a conceptual diagram for describing the method for forming an electrode in accordance with yet another exemplary embodiment; and

FIG. 7 is a conceptual diagram for describing a method for forming an electrode in accordance with still another exemplary embodiment.

### MODE FOR CARRYING OUT THE INVENTIVE CONCEPT

Hereinafter, embodiments of the present disclosure will be described in more detail with reference to the accompanying drawings. However, the present disclosure is not limited to the embodiments disclosed below, but will be implemented in various forms different from each other, and the embodiments are merely to complete the present disclosure, and are provided to fully convey the scope of the present disclosure to those skilled in the art. The drawings may be exaggerated to describe the embodiments of the present disclosure, and like reference numerals in the drawings refer to like elements.

The embodiments of the present disclosure relate to a method for forming an electrode of a semiconductor device, and more particularly, to a method for forming an electrode of a semiconductor device with improved electrical properties. More specifically, the embodiments of the present disclosure relate to a method for forming an electrode of a semiconductor device including a method for forming a low-resistance metal thin film layer.

As a specific example, the semiconductor device may be a NAND flash, and the electrode may be a gate electrode of the NAND flash. However, the electrode formed by the method in accordance with the embodiments is not limited to a gate electrode, and may be various components that require conductivity, for example, a word line of a NAND flash. In addition, the electrode formed by the method in accordance with the embodiments is not limited to a NAND flash, and may be applied to a thin film that requires conductivity in various semiconductor devices.

### Embodiment 1

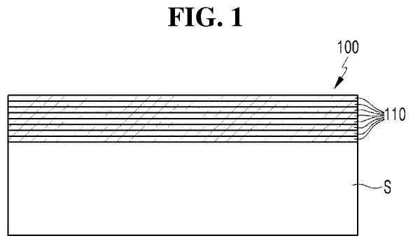

FIG. 1 is a diagram illustrating a state in which an electrode in accordance with an exemplary embodiment is formed on a substrate.

Referring to FIG. 1, a electrode 100 may be formed on a substrate S. Here, the substrate S may be a wafer, which may be one of a Si wafer, a Gallium Aresenide (GaAs) wafer, and a Silicon Germanium (SiGe) wafer.

The electrode 100 may be a laminate body formed by the stacking of a plurality of metal thin film layers 110. In addition, each of the plurality of metal thin film layers 110 may have been formed by using a precursor raw material containing ruthenium (Ru), which is a low-resistance metal. Accordingly, the electrode 100 may be an electrode containing ruthenium (Ru), or an electrode made of ruthenium (Ru).

In addition, the metal thin film layer 110 may have been formed by using a precursor raw material containing molybdenum (Mo). Accordingly, the electrode 100 may be an electrode containing molybdenum (Mo).

In addition, the metal thin film layer 110 may be formed by using a precursor raw material containing ruthenium (Ru) and molybdenum (Mo), and accordingly, the electrode 100 may be an electrode containing ruthenium (Ru) and molybdenum (Mo).

Hereinafter, with reference to FIG. 1 to FIG. 3, a method for forming an electrode on a substrate in accordance with an exemplary embodiment will be described.

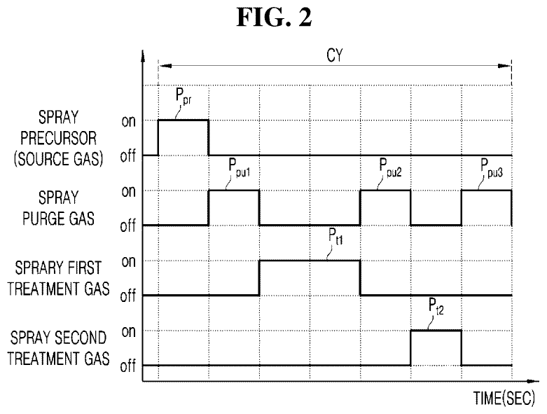

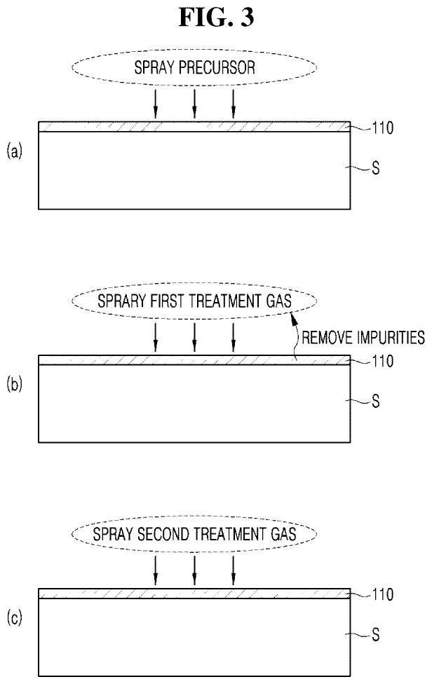

FIG. 2 is a conceptual diagram for describing the method for forming an electrode in accordance with an exemplary embodiment. FIG. 3 is a process diagram conceptually illustrating the method for forming an electrode in accordance with an exemplary embodiment.

In FIG. 2, the term ‘on’ may mean that a raw material for a process is sprayed, and the term ‘off’may mean that the spraying of the raw material is stopped or terminated.

Referring to FIG. 2 and FIG. 3, a method for forming the electrode 100 includes a step of spraying a precursor containing at least one of ruthenium (Ru) and molybdenum (Mo) towards the substrate S to form the metal thin film layer 110 (precursor spraying step Ppr), a step of spraying a gas containing oxygen (O2) (hereinafter, a first treatment gas) to remove impurities from the metal thin film layer 110 (first treatment step Pt1), and an annealing step of spraying a gas containing at least one of hydrogen (H2), argon (Ar), and helium (He) (hereinafter, a second treatment gas) to increase the temperature inside a chamber in which the process is performed, thereby reducing voids of the metal thin film layer 110 (second treatment step Pt2).

In addition, the method for forming the electrode 100 may include a step of spraying a purge gas. That is, the method may include a first purge step Ppu1 of spraying a purge gas between the precursor spraying step Ppr and the impurities removal step (the first treatment step Pt1), a second purge step Ppu2 of spraying a purge gas between the impurities removal step (the first treatment step Pt1) and the annealing step (the second treatment step Pt2), and a third purge step Ppu3 of spraying a purge gas after the annealing step (the second treatment step Pt2) is terminated.

In summary, the above-described method for forming the electrode 100 may include the precursor spraying step Ppr, the first purge step Ppu1, the impurities removal step (the first treatment step Pt1), the second purge step Ppu2, the annealing step (the second treatment step Pt2), and the third purge step Ppu3.

In addition, the precursor spraying step Ppr—the first purge step Ppu1—the impurities removal step (the first treatment step Pt1)—the second purge step Ppu2—the annealing step (the second treatment step Pt2)—the third purge step Ppu3 as described above may be set as one process cycle CY for forming the metal thin film layer 110. In addition, the above-described process cycle CY are repeated a plurality of times to deposit or stack a plurality of metal thin film layers 110 as shown in FIG. 1. Accordingly, an electrode 100 in which the plurality of metal thin film layers 110 are stacked or the electrode 100 of a semiconductor device including the plurality of metal thin film layers 110 is formed. At this time, the number of repetitions of the process cycle CY may be adjusted according to a target thickness of the electrode 100 to be formed.

In the above, it has been described that one process cycle CY includes all of the first to third purge steps Ppu1, Ppu2, and Ppu3. However, without being limited thereto, some of the first to third purge steps Ppu1, Ppu2, and Ppu3 may be performed, and others thereof may be omitted. At this time, it is preferable that the second purge step Ppu2 is performed, and at least one of the first and third purge steps Ppu1 and Ppu3 is omitted.

In FIG. 1, in order to distinguish metal thin film layers formed by a plurality of process cycles CY, each metal thin film layer 110 is shown separately, but the plurality of metal thin film layers 110, which are stacked, may be in the form of a single body.

In addition, each ‘step’ included in one process cycle CY may be expressed as a ‘process.’ That is, the process cycle CY may be described as including ‘the precursor spraying process Ppr—the first purge process Ppu1—the impurities removal process (the first treatment process Pt1)—the second purge process Ppu2—the annealing process (the second treatment process Pt2)—the third purge process Ppu3.’

Hereinafter, each step included in the process cycle CY will be described in detail. At this time, for the convenience of explanation, the step Pt1 of spraying the first treatment gas containing oxygen (O2) to remove impurities will be named and described as the ‘first treatment step Pt1.’ In addition, the step Pt2 of spraying the second treatment gas containing at least one of H2, Ar, and He to anneal the metal thin film layer 110 will be named and described as the ‘second treatment step Pt2.’

In the precursor spraying step Ppr, a precursor raw material containing at least one of ruthenium (Ru) and molybdenum (Mo) is sprayed into the chamber in which the substrate S is loaded.

A precursor raw material containing ruthenium (Ru) may be, for example, a raw material containing bis(ethylcyclopentadienyl)ruthenium ((EtCp)2Ru). In addition, a precursor raw material containing molybdenum (Mo) may be, for example, a raw material containing at least one of molybdenum hexacarbonyl and molybdenum pentachloride. Here, the precursor raw material containing ruthenium (Ru) may be named as a ‘source containing ruthenium (Ru)’ and the precursor raw material containing molybdenum (Mo) may be named as a ‘source containing molybdenum (Mo).’

The precursor raw material containing at least one of ruthenium (Ru) and molybdenum (Mo) may be an organic substance. In addition, the precursor raw material may be solid or liquid. Accordingly, a precursor in a solid phase or liquid phase is heated and converted into a gas before being sprayed, and then the precursor in a gas phase is sprayed on the substrate S. When a precursor is sprayed toward the substrate S, the precursor or a metal element included in the precursor, that is, at least one of ruthenium (Ru) and molybdenum (Mo), is adsorbed onto the substrate S. Accordingly, as shown in (a) of FIG. 3, the metal thin film layer 110 is formed on the substrate S. That is, the metal thin film layer 110 containing at least one of ruthenium (Ru) and molybdenum (Mo) is formed.

When the precursor spraying step Ppr is terminated, a purge gas is sprayed into the chamber and purged (the first purge step Ppu1). At this time, for example, an Ar gas may be used as the purge gas.

Meanwhile, the precursor raw material containing at least one of ruthenium (Ru) and molybdenum (Mo) may include at least one ligand among carbon (C), hydrogen (H), and oxygen (O), depending on the type of the material. Accordingly, the metal thin film layer 110 on which the precursor raw material containing at least one of ruthenium (Ru) and molybdenum (Mo) has been sprayed and deposited may include at least one ligand among carbon (C), hydrogen (H), and oxygen (O). In addition, ligands such as carbon (C), hydrogen (H), and oxygen (O) included in the metal thin film layer 110 act as impurities that increase resistance.

Therefore, in the embodiment, after a precursor is sprayed to form a metal thin film layer 110, a step of removing impurities, which is at least one ligand among the carbon (C), hydrogen (H), and oxygen (O) impurities, from the metal thin film layer 110 is performed, i.e., the first treatment step Pt1.

Hereinafter, the first treatment step Pt1 will be described.

The first treatment step Pt1 is a step of removing impurities from the metal thin film layer 110. The first treatment step Pt1 includes a step of spraying the first treatment gas containing oxygen (O2) into the chamber. Here, the first treatment gas containing oxygen (O2) may be, for example, a pure oxygen (O2) gas, or air. However, without being limited thereto, a variety of gases containing oxygen (O2) may be used as the first treatment gas.

The first treatment step Pt1 may be performed after the precursor spraying step Ppr and the purge gas spraying step (the first purge step Ppu1) are terminated. In other words, the precursor spraying step Ppr and the purge gas spraying step (the first purge step Ppu1) are sequentially performed, and the first treatment step Pt1 may be performed by spraying the first treatment gas.

The inside of the chamber in which the substrate S is loaded or in which a process is performed is heated to a predetermined temperature or higher. That is, the inside of the chamber may be in a state in which a process temperature for forming the metal thin film layer 110 is maintained, e.g., approximately 200° C. to approximately 400° C. More specifically, the inside of the chamber may be controlled to maintain the temperature at approximately 250° C. to approximately 300° C. When the first treatment gas is sprayed into the chamber, a ligand contained in the metal thin film layer 110, such as the carbon (C) ligand, reacts with oxygen (O2). That is, a combustion reaction occurs between the oxygen (O2) contained in the first treatment gas and the carbon (C) ligand, so that carbon (C) is separated from the metal thin film layer 110. In other words, the carbon (C) ligand bond contained in the precursor of the metal thin film layer 110 is broken and falls out of the metal thin film layer 110. Accordingly, the content of at least one of the ligand impurities of carbon (C), hydrogen (H), and oxygen (O) contained in the metal thin film layer 110 may be reduced, or the ligand impurities may be removed from the metal thin film layer 110.

As described above, in the first treatment step, the temperature inside the chamber is maintained at approximately 200° C. to approximately 400° C., preferably approximately 250° C. to approximately 300° C. Accordingly, a combustion reaction between the oxygen (O2) contained in the first treatment gas and a ligand may be facilitated. That is, the combustion reaction between the oxygen (O2) contained in the first treatment gas and a ligand contained in the metal thin film layer 110 may be facilitated due to heat inside the chamber. Therefore, the combustion reaction between the oxygen (O2) contained in the first treatment gas and a ligand contained in the metal thin film layer 110 or the precursor may be described as a thermal reaction.

After the first treatment step Pt1 is terminated, a purge gas is sprayed into the chamber and purged (the second purge step Ppu2). At this time, the purge gas may be the same gas as the gas used in the first purge step Ppu1, and for example, an Ar gas may be used.

The second treatment step Pt2 may be a process of annealing the metal thin film layer 110 to reduce voids. The second treatment step Pt2 includes, as shown in FIG. 2 and (c) of FIG. 3, a step of spraying the second treatment gas into the chamber. At this time, the second treatment gas may include at least one gas among hydrogen (H2), argon (Ar), and Helium (He).

In spraying the second treatment gas into the chamber, the spraying is performed such that the pressure inside the chamber is increased compared to that before the spraying of the second treatment gas. At this time, it is preferable that the pressure inside the chamber increases to approximately 5 torr to approximately 7 torr, and the second treatment gas is sprayed for 10 seconds or more.

The reason for spraying the second treatment gas to increase the pressure inside the chamber to approximately 5 torr to approximately 7 torr is to increase the temperature inside the chamber. For example, before the spraying of the second treatment gas or in the first treatment step, the temperature inside the chamber may be approximately 250° C. to approximately 300° C. Thereafter, when the second treatment gas is sprayed such that the pressure inside the chamber becomes approximately 5 torr to approximately 7 torr, the temperature inside the chamber may be increased to approximately 350° C. to approximately 400° C. In other words, the pressure increase caused by the spraying of the second treatment gas may increase the temperature inside the chamber. In addition, as the pressure is increased to approximately 5 torr to approximately 7 torr, the temperature inside the chamber during the second treatment step may be controlled to be higher than that during the first treatment step.

As the temperature inside the chamber is increased, the substrate S, or the metal thin film layer 110 deposited on the substrate S may be annealed. Accordingly, grains contained in the metal thin film layer 110 are expanded, so that voids between the grains may be reduced or made smaller. As the voids are reduced by the annealing, the resistance of the metal thin film layer 110 or the electrode 100 may decrease. That is, it is possible to form the metal thin film layer 110 or the electrode 100 with low resistance.

Meanwhile, in spraying the second treatment gas, when the spraying is performed such that the pressure inside the chamber becomes less than 5 torr, the grains of the metal thin film layer 110 may not be expanded or may not be sufficiently expanded due to a low temperature inside the chamber. For example, the temperature inside the chamber may be lower than approximately 350° C., so that the grains of the metal thin film layer 110 may not be expanded or may not be sufficiently expanded. In addition, in order to expand the grains of the metal thin film layer 110, the temperature inside the chamber is controlled to be approximately 350° C. to approximately 400° C., and to this end, it is sufficient that the pressure of the chamber is approximately 7 torr or lower.

Therefore, in spraying the second treatment gas, the pressure inside the chamber is controlled to be approximately 5 torr to approximately 7 torr.

As described above, the second treatment gas used in the second treatment step includes at least one among hydrogen (H2), argon (Ar), and helium (He). At this time, when a gas containing hydrogen (H2) is used as the second treatment gas, impurities remaining in the metal thin film layer 110 may be further removed in the second treatment step. That is, in the metal thin film layer 110, at least one among the ligand impurities of carbon (C), hydrogen (H), and oxygen (O) that has not been removed in the first treatment step may remain. The ligand impurities may be further removed by hydrogen (H2) contained in the second treatment gas. In other words, at least one ligand bond among the carbon (C), hydrogen (H), and oxygen (O) contained in the metal thin film layer 110 may be broken by the hydrogen (H2) contained in the second treatment gas and removed. Accordingly, at least one of the ligand impurities of the carbon (C), hydrogen (H), and oxygen (O) contained in the metal thin film layer 110 may have a reduced content, or removed.

The second treatment step Pt2 may include a step of generating plasma. That is, the second treatment step Pt2 may include a step of generating plasma by using the second treatment gas while spraying the second treatment gas. More specifically, the second treatment gas is sprayed into the chamber or towards the substrate S, and power for generating plasma is supplied. At this time, for example, radio frequency (RF) power is applied to at least one among the chamber, a susceptor on which the substrate S is seated inside the chamber, and a spraying part for spraying the second treatment gas into the chamber. Accordingly, plasma containing at least one among hydrogen (H2), argon (Ar), and helium (He) may be generated inside the chamber.

The plasma may promote the annealing of the metal thin film layer 110. In other words, compared to a case of spraying the second treatment gas without generating plasma, when plasma is generated while spraying the second treatment gas, an annealing reaction may occur more quickly to shorten the time for annealing.

After the second treatment step Pt2 is terminated, a purge gas is sprayed into the chamber and purged (the third purge step Ppu3). At this time, the purge gas may be the same gas as the gas used in the first and second purge steps Ppu1 and Ppu2, and for example, an Ar gas may be used.

Thereafter, the process cycle CY including ‘the precursor spraying step Ppr—the first purge step Ppu1—the first treatment step Pt1—the second purge step Ppu2—the second treatment step Pt2—the third purge step Ppu3’ as described above may be repeated a plurality of times and performed. Accordingly, a plurality of metal thin film layers 110 are formed on the substrate S as shown in FIG. 1, and accordingly the electrode 100 having a predetermined thickness is formed.

### Embodiment 2

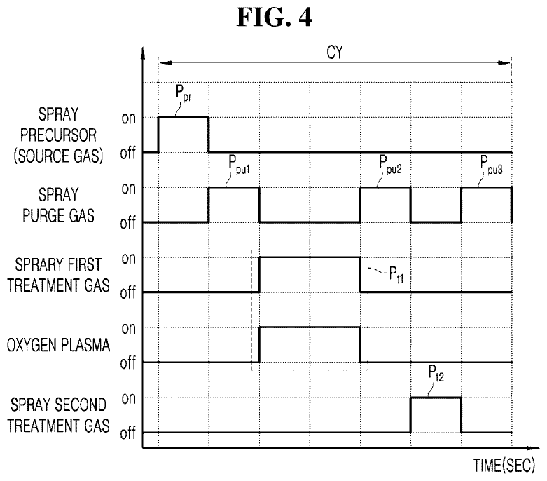

FIG. 4 is a conceptual diagram showing a method of forming a metal thin film layer on a substrate in accordance with another exemplary embodiment.

In FIG. 4, the term ‘on’ may mean spraying a raw material for the process, or generating plasma. In addition, the term ‘off’ may mean that the raw material spraying or the plasma generation is stopped or terminated.

The method in accordance with another exemplary embodiment may be the same as the exemplary embodiment in the precursor spraying step Ppr, the first to third purge steps Ppu1 to Ppu3, and the second treatment step Pt2 may be different therefrom in the first treatment step Pt1.

A first treatment step Pt1 in accordance with another exemplary embodiment may include a step of generating plasma. That is, the first treatment step Pt1 may include, as shown in FIG. 4, a step of spraying a first treatment gas, and a step of generating oxygen plasma using the sprayed first treatment gas. More specifically, the first treatment gas is sprayed into a chamber or towards a substrate S, and power for generating plasma is supplied. At this time, for example, radio frequency (RF) power is applied to at least one among the chamber, a susceptor on which the substrate S is seated inside the chamber, and a spraying part for spraying a gas into the chamber. At this time, it is preferable that the power applied for the plasma generation is controlled to be approximately 500 W to approximately 1000 W (approximately 500 watts to approximately 1000 watts). Accordingly, plasma is generated inside the chamber. At this time, since the first treatment gas contains oxygen (O2), the plasma generated in the first treatment step may be ‘oxygen plasma.’

When the oxygen plasma is generated in the first treatment step Pt1, a combustion reaction between ligand impurities contained in a metal thin film layer 110 and oxygen (O2) may be promoted. That is, as the temperature inside the chamber is maintained at approximately 250° C. to approximately 300° C., the combustion reaction between the ligand impurities and the oxygen (O2) occurs due to heat inside the chamber, and since the oxygen plasma is generated on top of the reaction, the combustion reaction between the ligand impurities and the oxygen (O2) may be promoted. Therefore, compared to a case of only spraying the first treatment gas, when plasma is generated while spraying the first treatment gas, it is possible to increase at least one of a removal amount of impurities and a removal rate of impurities. Accordingly, it is possible to more effectively remove ligand impurities resulting from a precursor.

Meanwhile, when the power applied in the first treatment step Pt1 is lower than 500 W, the effect of promoting a combustion reaction by oxygen plasma may be insignificant. In addition, when the power applied in the first treatment step Pt1 is higher than 1000 W, an amount in which the metal thin film layer 110 is converted into a gaseous or gas-phase metal oxide, e.g., RuO4(gas), by oxygen plasma may be large, so that the metal thin film layer 110 may be etched in a large quantity. Accordingly, in forming an electrode 100 by stacking a plurality of metal thin film layers 110 by performing a process cycle CY a plurality of times, there may be a problem in that it takes a long time to form the electrode 100 to a target thickness. Therefore, in the first treatment step Pt1 power of approximately 500 W to approximately 1000 W is applied to generate the oxygen plasma.

### Embodiment 3

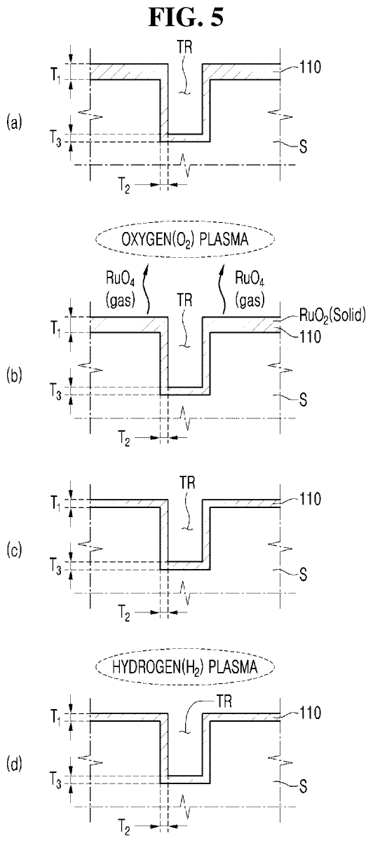

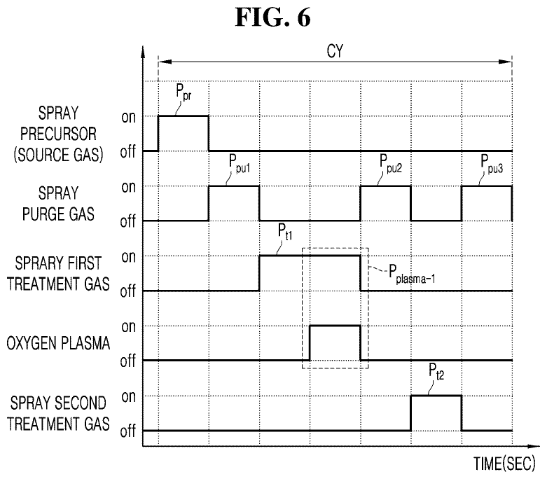

FIG. 5 is a process diagram conceptually illustrating a method for forming an electrode in accordance with yet another exemplary embodiment. FIG. 6 is a conceptual diagram for describing the method for forming an electrode in accordance with yet another exemplary embodiment.

In FIG. 6, the term ‘on’ may mean spraying a raw material for the process, or generating plasma. In addition, the term ‘off’ may mean that the raw material spraying or the plasma generation is stopped or terminated.

In the exemplary and another exemplary embodiments described above, it has been described that the electrode 100 is formed by depositing the metal thin film layer 110 on the planar substrate S. However, without being limited thereto, as shown in FIG. 5, an electrode 100 may be formed by depositing a metal thin film layer 110 on a substrate S having a trench TR.

Meanwhile, when the metal thin film layer 110 is formed on the substrate S having the trench TR, as shown in (a) of FIG. 5, an over-hang problem may occur, in which the thickness T1 of a metal thin film layer 110 deposited on an upper surface of the substrate S is greater than the thicknesses T2 and T3 of metal thin film layers 110 deposited on an inner wall surface forming the trench TR. In other words, when the precursor spraying step Ppr and the first treatment process Pt1 are terminated, the thickness of the metal thin film layer 110 deposited on the substrate S may vary for each position. At this time, as shown in (a) of FIG. 5, the thickness T1 deposited on the upper surface of the substrate S may be different from the thicknesses T2 and T3 deposited on the inner wall surface forming the trench TR. Accordingly, in forming the electrode 100 by depositing the metal thin film layer 110 on the substrate S having the trench TR, it is necessary to reduce the over-hang or prevent the occurrence of the over-hang.

When the metal thin film layer 110 is deposited by the method in accordance with yet another embodiment, the over-hang may be reduced or the occurrence of the over-hang may be prevented. That is, by reducing the difference between the thicknesses T2 and T3 of the metal thin film layers 110 deposited on the inner wall surface forming the trench TR and the thickness T1 of the metal thin film layer 110 deposited on the upper surface of the substrate S, it is possible to improve step coverage.

Hereinafter, with reference to FIG. 5 and FIG. 6, the method for forming an electrode in accordance with yet another exemplary embodiment will be described.

Referring to FIG. 6, the method in accordance with yet another exemplary embodiment may include a precursor spraying step Ppr of spraying a precursor containing ruthenium (Ru) and molybdenum (Mo) towards a substrate S to form a metal thin film layer 110, a first treatment step Pt1 of spraying a first treatment gas containing oxygen (O2) to remove impurities included in the metal thin film layer 110, a step Pplasma-1 of etching a portion of the metal thin film layer deposited on an upper surface of the substrate S by generating oxygen plasma while spraying the first treatment gas, and a step Pt2 of spraying a second treatment gas containing hydrogen (H2) to reduce a metal oxide (solid) generated in the etching step Pplasma-1 to a metal.

Here, the step of reducing a metal oxide (solid) to a metal is named as the ‘second treatment step Pt2’ since the second treatment gas containing hydrogen (H2) is sprayed as in the exemplary and another exemplary embodiments described above. In addition, hereinafter, for the convenience of explanation, the step Pplasma-1 of etching a portion of the metal thin film layer 110 deposited on an upper surface of the substrate S by generating oxygen plasma while spraying the first treatment gas is named as a ‘first plasma treatment step Pplasma-1’((b) of FIG. 5).

Therefore, the method for forming an electrode in accordance with yet another exemplary embodiment may include the precursor spraying step Ppr, the first purge step Ppu1, the first treatment step Pt1, the first plasma treatment step Pplasma-1, the second purge step Ppu2, the second treatment step Pt2, and the third purge step Ppu3.

In addition, in the method for forming an electrode in accordance with yet another exemplary embodiment, one process cycle CY may include ‘the precursor spraying step Ppr—the first purge step Ppu1—the first treatment step Pt1—the first plasma treatment step Pplasma-1—the second purge step Ppu2—the second treatment step Pt2—the third purge step Ppu3,’ and the process cycle CY may be repeated a plurality of times and performed.

Since the precursor spraying step Ppr, and the first to third purge steps Ppu1 to Ppu3 are similar to those of the exemplary and another exemplary embodiments, descriptions thereof will be omitted.

The above-described first treatment step Pt1 in accordance with another exemplary embodiment includes the first treatment gas spraying step and the oxygen plasma generation step. That is, as illustrated in FIG. 4, the first treatment step Pt1 in accordance with another exemplary embodiment continues to generate oxygen plasma while spraying the first treatment gas. In other words, while spraying the first treatment gas, power for generating plasma is applied by applying radio frequency (RF) power to at least one of a susceptor on which the substrate S is seated and a spraying part for spraying the first treatment gas into a chamber. Therefore, while the first treatment gas is being sprayed, oxygen (O2) plasma is generated inside the chamber.

However, the first treatment step Pt1 in accordance with yet another exemplary embodiment includes a step of spraying the first treatment gas, but does not include a step of generating plasma. In addition, the first plasma treatment step Pplasma-1 performed after the first treatment step Pt1 includes the step of spraying the first treatment gas and a step of generating plasma by using the first treatment gas. In other words, plasma is not generated during a first set period of time after the start of spraying the first treatment gas (first treatment step (Pt1)), and then oxygen plasma is generated simultaneous with the spraying of the first treatment gas during a second set period of time from the time the first set time elapses (first plasma treatment step (Pplasma-1). In other words, power for generating plasma is not applied during the first set period of time after the start of spraying the first treatment gas (first treatment step (Pt1)), and then the power for generating plasma is applied to generate oxygen plasma while spraying the first treatment gas during a second set period of time from the time the first set time elapses (first plasma treatment step (Pplasma-1). The step of generating plasma while spraying the first treatment gas is defined as the first plasma treatment step Pplasma-1 in yet another exemplary embodiment.

Hereinafter, with reference to FIG. 5, the method in accordance with yet another exemplary embodiment will be described in more detail.

When the precursor is sprayed on the substrate S and then the first treatment gas containing oxygen (O2) is sprayed, the metal thin film layer 110 formed on the substrate S may be, for example, the same as shown in (a) of FIG. 5. That is, the thickness T1 of a metal thin film layer deposited on the upper surface of the substrate S may be greater than the thicknesses T2 and T3 of metal thin film layers deposited on the inner wall surface forming the trench TR.

After the first treatment step Pt1 of spraying the first treatment gas to remove impurities is terminated, the first plasma treatment step Pplasma-1 is performed. That is, the first plasma treatment step Pplasma-1 of generating plasma by using a first treatment gas while spraying the first treatment gas is performed. To this end, radio frequency (RF) power is applied to at least one of a susceptor on which the substrate S is seated and a spraying part for spraying a gas into a chamber while spraying the first treatment gas containing oxygen (O2) into the chamber. Accordingly, oxygen plasma is generated inside the chamber as shown in (b) of FIG. 5.

When the oxygen plasma is generated inside the chamber, a reaction occurs between a metal contained in the metal thin film layer 110 and oxygen (O2). In addition, the reaction generates a solid metal oxide and a gaseous metal oxide. For example, when the oxygen plasma is generated inside the chamber, a reaction occurs between ruthenium (Ru) contained in the metal thin film layer 110 and oxygen (O2). Accordingly, a solid-phase RuO2 (solid) and a gaseous-phase RuO4 (gas) are generated (see (b) of FIG. 5). Among these, the solid-phase RuO2 (solid) remains in the metal thin film layer 110, and the RuO4 (gas) is removed in a gas phase from the metal thin film layer 110. That is, an etching reaction occurs in which a portion of the metal thin film layer 110 is converted to a gaseous metal oxide, e.g., RuO4, and removed.

The etching mainly occurs in the metal thin film layer 110 deposited on the upper surface of the substrate S. This is because as the oxygen plasma is generated on an upper side of the substrate S, the metal thin film layer 110 formed on the upper surface of the substrate S is closer to the oxygen plasma than the metal thin film layer 110 formed on the inner wall surface forming the trench TR. Accordingly, when the oxygen plasma is generated, the etching rate and the etched thickness of the metal thin film layer 110 formed on the upper surface of the substrate are greater than the etching rate and etched thickness of the metal thin film layer 110 formed on the inner wall surface forming the trench TR. Therefore, when the first plasma treatment step Pplasma-1 for generating oxygen plasma is performed, as shown in (c) of FIG. 5, the difference between the thicknesses T2 and T3 of the metal thin film layers 110 formed on the inner wall surface forming the trench TR and the thickness T1 of the metal thin film layer 110 formed on the upper surface of the substrate S is reduced.

The second treatment step Pt2 is a process performed after the first plasma treatment step Pplasma-1, and is a process in which the metal oxide generated in the first plasma treatment step Pplasma-1 is reduced to a metal. The second treatment step Pt2 includes a step of spraying the second treatment gas containing hydrogen (H2). When the second treatment gas containing hydrogen (H2) is sprayed, a metal oxide in a metal thin film layer reacts with hydrogen and is reduced back to a metal. For example, RuO2 (solid), which the metal oxide generated in the first plasma treatment step Pplasma-1, reacts with hydrogen (H2) and is reduced to ruthenium (Ru), which is a metal.

In addition, in performing the second treatment step Pt2, plasma may be generated. That is, the second treatment step Pt2 may include a step of spraying of a second treatment gas and a step of generating plasma by using the second treatment gas. At this time, as the second treatment gas contains hydrogen (H2), the plasma generated in the second treatment step Pt2 may be described as hydrogen plasma. In addition, the hydrogen plasma may promote the reaction of reducing a metal oxide to a metal. Accordingly, the time required to reduce the metal oxide to the metal may be shortened.

As described above, the first plasma treatment step Pplasma-1 in which a metal is generated is performed before the second treatment step Pt2. Therefore, the first plasma treatment step Pplasma-1 may be named as a ‘pre-treatment step Pplasma-1,’ which is performed before the second treatment step Pt2.

### Embodiment 4

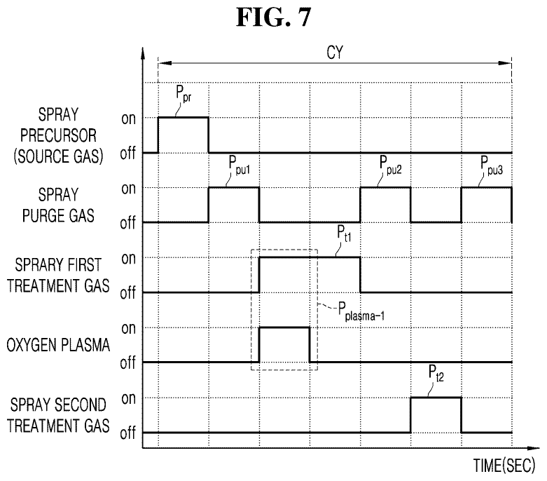

FIG. 7 is a conceptual diagram for describing a method for forming an electrode in accordance with still another exemplary embodiment.

In FIG. 7, the term ‘on’ may mean spraying a raw material for the process, or generating plasma. In addition, the term ‘off’ may mean that the raw material spraying or the plasma generation is stopped or terminated.

Still another exemplary embodiment is similar to yet another exemplary embodiment described above. However, in still another exemplary embodiment, as illustrated in FIG. 7, the first plasma treatment step Pplasma-1 is performed, and then the first treatment step Pt1 is performed. That is, a process cycle CY in accordance with still another exemplary embodiment is performed in the order of ‘the precursor spraying step Ppr—the first purge step Ppu1—the first plasma treatment step Pplasma-1—the first treatment step Pt1—the second purge step Ppu2—the second treatment step Pt2—the third purge step Ppu3.’

When the third treatment step Pt3 of forming oxygen plasma is performed and then the first treatment step Pt1 of spraying a gas containing oxygen (O2) is performed, the time required to remove ligand impurities in the first treatment step Pt1 may be shortened. That is, compared to yet another exemplary embodiment in which the first treatment step Pt1 is first performed and then the first plasma treatment step Pplasma-1 is performed, still another exemplary embodiment in which the first plasma treatment step Pplasma-1 is first performed and then the first treatment step Pt1 is performed improves the rate at which ligand impurities are removed.

In the above, yet another exemplary embodiment and still another exemplary embodiment are described to be used to form the metal thin film layer 110 on the substrate S having the trench TR. However, without being limited thereto, any one of the above-described yet another exemplary embodiment and still another exemplary embodiment may be applied to form the metal thin film layer 110 on the substrate S on a plane, i.e., with no trench TR.

In addition, in the above, it has been described that the metal thin film layer 110 containing at least one of ruthenium (Ru) and molybdenum (Mo) is formed on the upper surface of the substrate S. However, without being limited thereto, a predetermined thin film (hereinafter, an underlayer) may be formed on the upper surface of the substrate S, and the metal thin film layer 110 containing at least one of ruthenium (Ru) and molybdenum (Mo) may be formed in an upper portion of the underlayer. At this time, the underlayer may be, for example, an active layer of a semiconductor device.

When the underlayer is indium gallium zinc oxide (IGZO), it is preferable that a gas not containing hydrogen (H2) is used as the second treatment gas sprayed in the second treatment step Pt2. This is because when IGZO is exposed to hydrogen (H2), electrical properties of the underlayer may be degraded. Therefore, when the underlayer is IGZO, it is preferable that a second treatment gas including a gas not containing hydrogen (H2), e.g., argon (Ar), is used to perform the second treatment step Pt2.

In addition, when the underlayer is indium gallium zinc oxide (IGZO), after the second treatment step Pt2 of spraying the second treatment gas containing argon (Ar) is terminated, a post-treatment step of spraying a gas containing hydrogen (H2) (hereinafter, a post-treatment gas) may be performed.

In summary, when the underlayer is indium gallium zinc oxide (IGZO), the process cycle CY may be performed in the order of ‘the precursor spraying step Ppr—the first purge step Ppu1—the first treatment step Pt1—the second purge step Ppu2—the second treatment step Pt2—the post-treatment step-the third purge step Ppu3.’ Here, the second treatment step Pt2 is a step of spraying of the second treatment gas containing argon (Ar), and the post-treatment step is a step of spraying the post-treatment gas containing hydrogen (H2). Since the second treatment gas containing argon (Ar) is sprayed and then the post-treatment gas containing hydrogen (H2) is sprayed (the post-treatment step), damage to an underlayer caused by hydrogen (H2) may be suppressed.

In the above-described embodiment, it has been described that a process cycle CY including the same steps is repeated a plurality of times. However, without being limited thereto, a plurality of process cycles using different gases may be alternately performed.

More specifically, a method for forming an electrode 100 may include a first process cycle CY1 and a second process cycle CY2. Here, the first process cycle CY1 may include a precursor spraying step Ppr of spraying a precursor containing at least one of ruthenium (Ru) and molybdenum (Mo) toward a substrate S to form a first metal thin film layer, a first treatment step Pt1 of spraying a first treatment gas containing oxygen (O2) to remove impurities from the first metal thin film layer, a purge step Ppu2 of spraying a purge gas after stopping the spraying of the first treatment gas, and a second treatment step Pt2 of spraying a second treatment gas containing argon (Ar). In addition, the second process cycle CY2 may include a precursor spraying step Ppr of spraying a precursor containing at least one of ruthenium (Ru) and molybdenum (Mo) on the first metal thin film layer to form a second metal thin film layer, a third treatment step Pt3 of spraying a gas (hereinafter, a third treatment gas) containing oxygen (O2) to remove impurities from the second metal thin film layer, a purge step Ppu2 of spraying a purge gas after stopping the spraying of the third treatment gas, and a fourth treatment step Pt4 of spraying a fourth treatment gas containing hydrogen (H2).

The third treatment gas used in the second process cycle CY2 is a gas containing oxygen (O2) as described above, and may be the same gas as the first treatment gas used in the first process cycle CY1.

In addition, the second process cycle CY2 may further include a step of spraying a gas containing argon (Ar) between the purge step Ppu2 and the fourth treatment step Pt4.

As described above, according to the embodiments, it is possible to form an electrode from which ligand impurities resulting from a precursor containing at least one of ruthenium (Ru) and molybdenum (Mo) are removed. Accordingly, it is possible to prepare an electrode 100 with low resistance.

In addition, in forming the electrode 100 on a substrate S having a trench TR, step coverage may be improved by reducing the difference between the thickness of a metal thin film layer 110 formed on an inner wall forming the trench TR and the thickness of a metal thin film layer 110 formed on an upper surface of the substrate S.

### INDUSTRIAL APPLICABILITY

According to embodiments of the present disclosure, it is possible to form an electrode from which ligand impurities resulting from a precursor containing at least one of ruthenium (Ru) and molybdenum (Mo) are removed. Accordingly, it is possible to prepare an electrode with low resistance.

In addition, in forming an electrode on a substrate having a trench, step coverage may be improved by reducing the difference between the thickness of a thin film formed on an inner wall forming the trench and the thickness of a thin film formed on an upper surface of the substrate.

1. A method for forming an electrode, the method comprising:
a step of preparing a substrate;
a step of spraying a precursor containing ruthenium (Ru) on the substrate to form a metal thin film layer;
a first treatment step of spraying a first treatment gas containing oxygen (O₂) on the substrate;
a purge step of spraying a purge gas after stopping the spraying of the first treatment gas; and
a second treatment step of spraying a second treatment gas containing at least one of hydrogen (H₂), argon (Ar), and helium (He) on the substrate to anneal the metal thin film layer.

2. The method of claim 1, further comprising a first plasma treatment step performed after the first treatment step, and forming oxygen (O₂) plasma on the substrate.

3. The method of claim 1, further comprising a first plasma treatment step performed before the first treatment step, and forming oxygen (O₂) plasma on the substrate.

4. The method of claim 1, wherein the step of forming the metal thin film layer, the first treatment step, the purge step, and the second treatment step are repeated a plurality of times.

5. The method of claim 1, wherein the process temperature of the second treatment step is higher than that of the first treatment step.

6. The method of claim 1, wherein the pressure of the second treatment step is approximately 5 Torr to approximately 7 Torr.

7. The method of claim 1, wherein:
the substrate comprises a trench recessed downward from an upper surface thereof; and
the method further comprises a pre-treatment step of exposing the substrate on which the metal thin film layer is formed to oxygen plasma to convert a portion of the metal thin film layer into a gaseous metal oxide, thereby etching the metal thin film layer, wherein the pre-treatment step is performed between the first treatment step and the purge step, or between forming the metal thin film layer step and the first treatment step.

8. The method of claim 7, wherein:
when the portion of the metal thin film layer is converted into the gaseous metal oxide in the pre-treatment step, another portion of the metal thin film layer is converted into a solid metal oxide;
the second treatment gas sprayed in the second treatment step contains hydrogen (H₂); and
the second treatment step of spraying the second treatment gas containing hydrogen (H₂) is to react the hydrogen (H₂) contained in the second treatment gas with the solid metal oxide contained in the metal thin film layer, thereby reducing the solid metal oxide to a metal.

9. The method of claim 8, wherein the second treatment step comprises a step of generating hydrogen plasma by using the second treatment gas containing hydrogen (H₂).

10. A method for forming an electrode, the method comprising:
a step of preparing a substrate on which an indium gallium zinc oxide (IGZO) thin film layer is formed on one surface thereof;
a step of spraying a precursor containing ruthenium (Ru) on the IGZO thin film layer to form a metal thin film layer;
a first treatment step of spraying a first treatment gas containing oxygen (O₂) on the substrate to remove impurities included in the metal thin film layer;
a purge step of spraying a purge gas after stopping the spraying of the first treatment gas; and
a second treatment step of spraying a second treatment gas containing argon (Ar) on the substrate to anneal the metal thin film layer.

11. The method of claim 10, further comprising a post-treatment step performed after the second treatment step, and spraying a post-treatment gas containing hydrogen (H₂) on the substrate.

12. A method for forming an electrode, the method comprising:
a step of preparing a substrate;
a first process cycle step including a step of forming a first metal thin film layer on the substrate; and
a second process cycle step including a step of forming a second metal thin film layer on the first metal thin film layer,
wherein:
the first process cycle step includes:
a step of spraying a precursor containing ruthenium (Ru) on the substrate to form the first metal thin film layer;
a first treatment step of spraying a first treatment gas containing oxygen (O₂) on the substrate;
a purge step of spraying a purge gas after stopping the spraying of the first treatment gas; and
a second treatment step of spraying a second treatment gas containing argon (Ar) on the substrate, and
the second process cycle step includes:
a step of spraying a precursor containing ruthenium (Ru) on the first metal thin film layer to form the second metal thin film layer;
a third treatment step of spraying a third treatment gas containing oxygen (O₂) on the first metal thin film layer;
a purge step of spraying a purge gas after stopping the spraying of the third treatment gas; and
a fourth treatment step of spraying a fourth treatment gas containing hydrogen (H₂) on the first metal thin film layer.

13. The method of claim 12, wherein the fourth treatment step comprises a step of including a gas containing argon (Ar) before the spraying of the fourth treatment gas.
